(19) United States
(12) Patent Application Publication
(10) Pub. No.: US 2025/0275137 A1
(43) Pub. Date: Aug. 28, 2025

(54) SEMICONDUCTOR MEMORY DEVICE AND METHOD OF MANUFACTURING THE SAME

(71) Applicant: SK hynix Inc., Icheon-si Gyeonggi-do (KR)

(72) Inventors: Chi Soung KIM, Icheon-si Gyeonggi-do (KR); Jeong Hui AHN, Icheon-si Gyeonggi-do (KR); Young Sam LEE, Icheon-si Gyeonggi-do (KR); Sung Mok HONG, Icheon-si Gyeonggi-do (KR)

(73) Assignee: SK hynix Inc., Icheon-si Gyeonggi-do (KR)

(21) Appl. No.: 18/787,578

(22) Filed: Jul. 29, 2024

(30) Foreign Application Priority Data
Feb. 26, 2024 (KR) 10-2024-0027280

(51) Int. Cl. H10B 43/27

(52) U.S. Cl. CPC H10B 43/27

(57) ABSTRACT

A semiconductor memory device includes a chip formed in a cell array region of a substrate and including a plurality of structures and a plurality of channel pillars formed through the plurality of structures; and a plurality of dummy structures, at least one alignment key, and a first plurality of dummy pillars formed in an alignment area of a scribe lane of the substrate, the scribe lane configured to facilitate separation of plurality of chips. The at least one alignment key may extend through at least one of the plurality of dummy structures and extend into the substrate. The first plurality of dummy pillars is formed through the plurality of dummy structures and is formed around the alignment key.

### CROSS-REFERENCES TO RELATED APPLICATION

The present application claims priority under 35 U.S.C. § 119 (a) to Korean Patent Application number 10-2024-0027280, filed on Feb. 26, 2024, in the Korean Intellectual Property Office, which application is incorporated herein by reference in its entirety.

### BACKGROUND

### 1. Technical Field

Various embodiments generally relate to a semiconductor memory device and a method of manufacturing the same, including but not limited to a semiconductor memory device including a crack diffusion barrier and a method of manufacturing the semiconductor memory device.

### 2. Related Art

A three-dimensional (3D) non-volatile memory device includes a structure including a plurality of word lines and a plurality of sequentially stacked vertical contacts. Recently, as a demand for highly integrated semiconductor memory devices increases, the 3D non-volatile memory device needs a large amount of the word lines.

In the 3D non-volatile memory device, particularly, a memory block of a 3D NAND flash memory device is formed by stacking a plurality of word line structures in which a plurality of stacked word lines are stacked.

Because the memory block includes the plurality of word line structures, a height of the memory block exponentially increases, making difficult reading of an alignment key and an overlay pattern on a scribe lane of a substrate.

### SUMMARY

According to an embodiment, a semiconductor memory device is provided. The semiconductor memory device may include a chip formed in a cell array region of a substrate. The chip may include a plurality of structures and a plurality of channel pillars formed through the plurality of structures. A plurality of dummy structures, at least one alignment key, and a first plurality of dummy pillars may be formed in an alignment area of a scribe lane of the substrate, the scribe lane configured to facilitate separation of plurality of chips. The at least one alignment key may extend through at least one of the plurality of dummy structures and extend into the substrate. The first plurality of dummy pillars is formed through the plurality of dummy structures and is formed around the alignment key.

According to an embodiment, a semiconductor memory device is provided. The semiconductor memory device may include a first structure formed in a cell array region of a substrate, a second structure, and a third structure. The first structure may include a plurality of first channel pillars. The second structure may be arranged on the first structure. The second structure may include a plurality of second channel pillars corresponding to the plurality of first channel pillars. The third structure may be arranged on the second structure. The third structure may include a plurality of third channel pillars corresponding to the plurality of second channel pillars. A first dummy structure may be formed in an alignment area of the substrate. The first dummy structure may include a plurality of alignment keys disposed between a plurality of first dummy pillars. A second dummy structure may be arranged on the first dummy structure. The second dummy structure may include a second dummy pillars corresponding to the plurality of first dummy pillars. A third dummy structure may be arranged on the second dummy structure. The third dummy structure may include a plurality of third dummy pillars corresponding to the plurality of second dummy pillars.

According to an embodiment, a method of manufacturing a semiconductor memory device is provided. In the method of manufacturing the semiconductor memory device, a first plurality of insulating interlayers are alternately stacked with a first plurality of sacrificial layers to form a first preliminary structure on a cell array region of a substrate and to form a first preliminary dummy structure on a scribe lane of the substrate. A plurality of first sacrificial pillars may be formed in the first preliminary structure and the first preliminary dummy structure. A second plurality of insulating interlayers may be alternately stacked with a second plurality of sacrificial layers on the first preliminary structure and the first preliminary dummy structure to form a second preliminary structure on the first preliminary structure and a second preliminary dummy structure on the first preliminary dummy structure. A plurality of second sacrificial layers may be formed in the second preliminary structure and the second preliminary dummy structure, wherein each of the plurality of second sacrificial pillars may be connected to a different one of the plurality of first sacrificial pillars. A third plurality of insulating interlayer may be alternately stacked with the plurality of sacrificial layers on the second preliminary structure and the second preliminary dummy structure to form a third preliminary structure on the second preliminary structure and a third preliminary dummy structure on the second preliminary dummy structure. A plurality of holes may be formed in the third preliminary structure and the third preliminary dummy structure to expose the plurality of second sacrificial layers. The plurality of second sacrificial layers and the plurality of first sacrificial layers exposed through the plurality of holes may be removed to form a plurality of channel holes through the first preliminary structure, the second preliminary structure, and the third preliminary structure and to form a plurality of key holes through the first preliminary dummy structure, the second preliminary dummy structure, and the third preliminary dummy structure. The plurality of channel holes and the plurality of key holes may be filled. At least one alignment key may be formed between the plurality of first sacrificial pillars in the first preliminary dummy structure.

According to an embodiment, a semiconductor memory device may include a substrate including a cell array region and a scribe lane; a first plurality of insulating interlayers alternately stacked with a first plurality of second layers and forming a first structure on the cell array region and a first dummy structure on the scribe lane; a second plurality of insulating interlayers alternately stacked with a second plurality of second layers and forming a second structure on the first structure and a second dummy structure on the first dummy structure; and a third plurality of insulating interlayers alternately stacked with a third plurality of second layers and forming a third structure on the second structure and a third dummy structure on the second dummy structure. A plurality of dummy channel pillars may be formed through the first dummy structure, the second dummy structure, and the third dummy structure, and a plurality of alignment keys may be disposed in the first dummy structure between the plurality of dummy pillars, wherein the plurality of alignment keys do not extend into the third dummy structure.

### BRIEF DESCRIPTION OF THE DRAWINGS

The above and another aspects, features and advantages of the subject matter of the present disclosure will be more clearly understood from the following detailed description taken in conjunction with the accompanying drawings, in which:

FIG. 1 is a perspective view illustrating bonded wafers in accordance with an embodiment;

FIG. 2 is an enlarged perspective view illustrating section “A” in FIG. 1 in accordance with an embodiment;

FIG. 3 is a cross-sectional view illustrating a semiconductor memory device in accordance with an embodiment;

FIG. 4A, FIG. 5A, FIG. 6A, and FIG. 7A are plan views illustrating a semiconductor memory device formed utilizing a method of manufacturing a semiconductor memory device in accordance with an embodiment;

FIG. 4B, FIG. 5B, FIG. 6B, and FIG. 7B are cross-sectional views illustrating a semiconductor memory device formed utilizing a method of manufacturing a semiconductor memory device in accordance with an embodiment;

FIG. 8A to FIG. 8C are plan views illustrating a dummy structure of an overlay area in accordance with an embodiment;

FIG. 8D is a plan view illustrating an overlay area in accordance with an embodiment;

FIG. 9A to FIG. 9C are plan views illustrating a dummy structure of an overlay area in accordance with an embodiment; and

FIG. 9D is a plan view illustrating an overlay area in accordance with an embodiment.

### DETAILED DESCRIPTION

Various embodiments of the present disclosure are described in detail with reference to the accompanying drawings. Variations of the configurations or structures within the illustrations are possible, for example, due to manufacturing techniques and/or tolerances. Thus, the described embodiments should not be construed as limited to the particular configurations or structures illustrated but may include deviations in configuration and structure that do not depart from the spirit and scope of the present disclosure. The scope of the present disclosure is not limited to the examples or embodiments described in this specification, and those skilled in the art will understand that various modifications, additions, and substitutions related to these embodiments are possible without departing from the scope and technical concepts of the present disclosure.

The cross-hatching throughout the figures illustrates corresponding or similar areas between the figures rather than indicating the materials associated with the areas.

Terms such as “vertical,” “horizontal,” “top,” “bottom,” “under,” “over,” “on,” “side,” “upper,” “lower,” “left,” “level,” and other terms implying relative spatial relationship or orientation are utilized only for the purpose of ease of description or reference to a drawing and are not otherwise limiting. When one element is identified as “connected” to another element, the elements may be connected directly or through at least one intervening element between the elements. When two elements are identified as “directly connected,” one element is directly connected to the other element without an intervening element between the two elements. When one element is identified as “on,” “over,” or “under” another element, the elements may directly contact each other or an intervening element may be disposed between the elements.

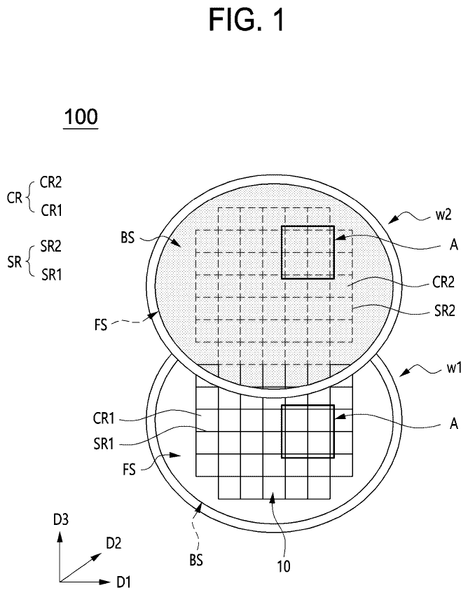

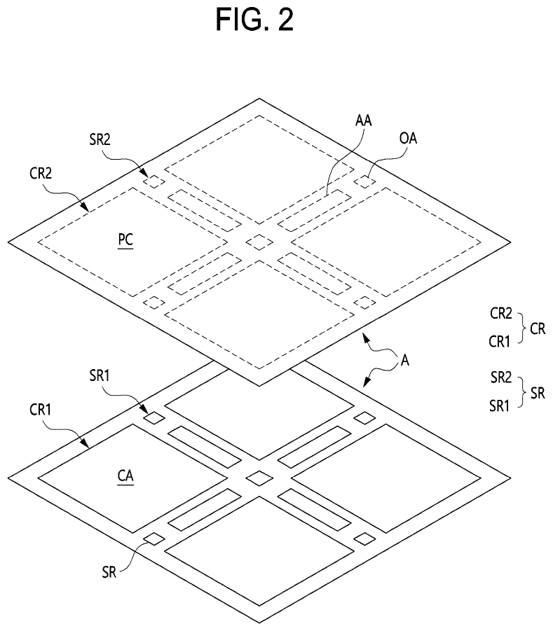

FIG. 1 is a perspective view illustrating bonded wafers in accordance with an embodiment, and FIG. 2 is an enlarged perspective view illustrating a section “A” in FIG. 1.

Referring to FIG. 1 and FIG. 2, a semiconductor device 100 of an embodiment include a first wafer w1 bonded to a second wafer w2 bonded. Each of the first and second wafers w1 and w2 include surfaces parallel to a first direction D1 and a second direction D2. The first wafer w1 and the second wafer w2 are stacked in a third direction D3. For example, the first wafer w1 and the second wafer w2 may include a silicon substrate, a silicon on insulator (SOI) substrate, a germanium substrate, a compound semiconductor substrate, and so forth.

Each of the first wafer w1 and the second wafer w2 include a first surface FS and a second surface BS. For example, the first surface FS of the first wafer w1 and the second wafer w2 includes a plurality of chip regions CR and a scribe lane SL configured to identify the chip regions CR.

In an embodiment, a cell array region CA of a 3D non-volatile memory device is integrated in chips CR1 of the first wafer w1. The cell array region CA includes a plurality of memory cells. The 3D non-volatile memory device may include a NAND flash memory. For example, the cell array region CA includes a stack structure. The stack structure includes a plurality of insulating interlayers, a plurality of conductive patterns, and a plurality of channel pillars. The plurality of insulating interlayers are alternately stacked with the plurality of conductive patterns. The plurality of channel pillars are formed through the stacked insulating interlayers and conductive patterns.

Control circuits PC configured to control the memory cells are integrated in a chips CR2 of the second wafer w2.

Scribe lanes SL1 and SL2 of the first wafer w1 and the second wafer w2 include at least one alignment area AA and at least one overlay area OA. At least one alignment key is formed in the alignment area AA. A plurality of overlay patterns may be formed in the overlay area OA. The scribe lanes SL1 and SL2 of the wafers w1 and w2 may further include a pattern region (not shown) where at least one test pattern, at least one monitoring pattern, and at least one chip guard ring pattern are formed. In an embodiment, the overlay area OA is positioned near a corner of the chip region CR. The alignment area AA is positioned between the overlay areas OA. An area of the alignment area AA may be larger than an area of the overlay area OA.

In an embodiment, the first wafer w1 corresponds to a semiconductor memory device formed in the cell array region CA of a substrate. The second wafer w2 corresponds to control circuits PC integrated on a substrate.

For example, the first wafer w1 and the second wafer w2 are bonded to each other such that the first surface FS of the first wafer w1 faces the first surface FS of the second wafer w2. In order to reduce a thickness of the semiconductor device 10, the second surface BS of the first wafer w1 and the second surface BS of the second wafer w2 may be grinded.

An alignment key formed in the scribe lane SL may include a device isolation trench, for example, an STI (shallow trench isolation) formed to provide device isolation within the substrate. When an integration degree of the semiconductor memory device increases, the quantity of stacked conductive patterns also increases such that a stack structure increases in height. As the height of the stack structure increases, reading the alignment key becomes difficult. In order to improve readability of the alignment key, the alignment key of the 3D non-volatile memory device is enlarged to have a deeper or increased depth and a large area greater than the area of the device isolation trench.

A large alignment key may, however, cause cracks when grinding the substrate. The cracks may spread outward from the alignment key in the first wafer w1, for example, along a horizontal direction, which cracks may cause changes in the characteristics or function of the semiconductor device, such as a 3D semiconductor memory device.

In an embodiment, in order to reduce the changes in the characteristics of the semiconductor memory device, a plurality of dummy pillars are formed as crack diffusion barriers in the alignment area AA and the overlay area OA. The dummy pillars have a structure and a shape substantially the same as or similar to the structure and shape of the channel pillar of the cell array region CA to reduce or prevent the crack from diffusing or spreading outward from the alignment area, for example, along the horizontal direction.

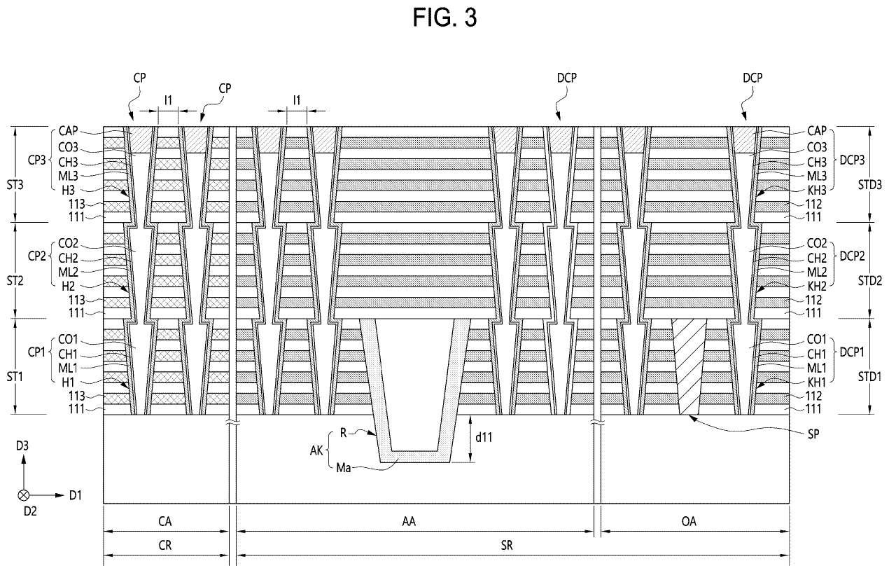

FIG. 3 is a cross-sectional view illustrating a semiconductor memory device in accordance with an embodiment.

Referring to FIG. 1 to FIG. 3, the chip region CR includes the cell array region CA. The scribe lane SL includes the alignment area AA and the overlay area OA.

The cell array region CA includes a plurality of structures. For example, the cell array region CA includes first to third structures ST1, ST2, and ST3 sequentially stacked on a semiconductor substrate 101. The semiconductor substrate 101 includes at least one source line.

In an embodiment, the first structure ST1 includes a plurality of insulating interlayers 111 alternately stacked with a plurality of conductive patterns 113. The insulating interlayers 111 may include silicon oxide. The conductive patterns 113 may include a metal. The conductive patterns 113 include at least one source selection line and a plurality of word lines associated with memory cell transistors. For example, the conductive patterns 113 extend in the first direction D1. The insulating interlayers 111 and the conductive patterns 113 are alternately stacked in the third direction D3, such as a vertical direction.

The first structure ST1 includes a plurality of first channel pillars CP1. Each of the first channel pillars CP1 is formed in a first channel hole H1 and includes a first memory layer ML1, a first channel layer CH1, and a first core layer CO1.

The first channel hole H1 is formed through the first structure ST1. The first channel hole H1 has a gradually decreased diameter from top to bottom of the first structure ST1. The first channel hole H1 may have a high aspect ratio. The first memory layer ML1 may have a conformal thickness along a sidewall and a bottom surface of the first structure ST1, which sidewall and surface are adjacent to the first channel hole H1. The first channel layer CH1 may have a conformal thickness along a surface of the first memory layer ML1. The first core layer CO1 is formed within the first channel layer CH1.

The second structure ST2 is arranged on or over the first structure ST1. The second structure ST2 includes a plurality of insulating interlayers 111 alternately stacked with a plurality of conductive patterns 113. The conductive patterns 113 of the second structure ST2 include a plurality of word lines associated with memory cell transistors. The second structure ST2 include a plurality of second channel pillars CP2 connected to the first channel pillars CP1. Each of the second channel pillars CP2 is formed in a second channel hole H2 and includes a second memory layer ML2, a second channel layer CH2, and a second core layer CO2. The second channel hole H2 is formed in the second structure ST2 in alignment with the first channel hole H1 or the first channel pillars CP1. The second channel hole H2 has a gradually decreased diameter from top to bottom of the second structure ST2. The second channel hole H2 may have a high aspect ratio. The second memory layer ML2 may have a conformal thickness along a sidewall of the second structure ST2, which sidewall is adjacent to the second channel hole H2. The second memory layer ML2 is connected to the first memory layer ML1. The second channel layer CH2 may have a conformal thickness along a surface of the second memory layer ML2. The second channel layer CH2 is connected to the first channel layer CH1. The second core layer CO2 is formed within the second channel layer CH2. The second core layer CO2 contacts the first core layer CO1.

The third structure ST3 is arranged or formed on the second structure ST2. The third structure ST3 includes a plurality of insulating interlayers 111 alternately stacked with a plurality of conductive patterns 113. The conductive patterns 113 of the third structure ST3 include word lines associated with memory cell transistors and at least one drain selection line.

The third structure ST3 includes a plurality of third channel pillars CP3 connected to the second channel pillars CP2. Each of the third channel pillars CP3 is formed in a third channel hole H3 and includes a third memory layer ML3, a third channel layer CH3, a third core layer CO3, and a capping layer CAP.

The third channel hole H3 is formed through the third structure ST3. The third channel hole H3 is formed in the third structure ST3 in alignment with the second channel hole H2 or the second channel pillars CP2. The third channel hole H3 has a gradually decreased diameter from top to bottom of the third structure ST3. The third channel hole H3 may have a high aspect ratio. The third memory layer ML3 may have a conformal thickness along a sidewall of the third structure ST3, which sidewall is adjacent to the third channel hole H3. The third memory layer ML3 is connected to the second memory layer ML2. The third channel layer CH3 may have a conformal thickness along a surface of the third memory layer ML3. The third channel layer CH3 is connected to the second channel layer CH2. The third core layer CO3 is partially formed within the third channel layer CH3. The third core layer CO3 contacts with the second core layer CO2. The capping layer CAP is formed on the third core layer CO3 to fill the third channel layer CH3. The capping layer CAP may include a semiconductor material such as silicon. The capping layer CAP and the third channel layer CH3 may include conductive impurities.

In an embodiment, the memory layers ML1, ML2, and ML3 may have substantially the same thickness and are electrically connected. The memory layers ML1, ML2, and ML3 may include various data storage materials such as a charge trapping layer, a ferroelectric layer, a phase change layer, a ferromagnetic layer, a nano dot, and so forth. Each of the memory layers ML1, ML2, and ML3 may include a blocking insulation layer, a data storage layer, and a tunnel insulation layer sequentially interposed between the structures ST1 to ST3 and the channel layers CH1 to CH3. The data storage layer may include silicon nitride for a charge trap. The tunnel insulation layer may include silicon oxide that facilitates charge tunneling. The blocking insulating layer may include an insulation material that blocks electric charge. For example, the blocking insulation layer may include at least one of silicon oxide and metal oxide.

The channel layers CH1, CH2, and CH3 may include a semiconductor layer such as silicon. The channel layers CH1, CH2, and CH3 are connected to each other along the third direction D3. The channel layers CH1, CH2, and CH3 may have a cylindrical shape or a tubular shape. The capping layer CAP fills a space over the channel layers CH1, CH2, and CH2, for example, having the cylindrical shape or the tubular shape.

The alignment area AA and the overlay area OA include a plurality of dummy structures stacked on the substrate 101. The dummy structures have a height substantially the same as a height of the structures of the cell array region CA. For example, the alignment area AA includes a first dummy structure STD1, a second structure STD2, and a third dummy structure STD3 sequentially stacked on the substrate 101.

In an embodiment, the first dummy structure STD1 is positioned on a same level as a level of the first structure ST1. Thus, the first dummy structure STD1 has a height substantially the same as the height of the first structure ST1. The first dummy structure STD1 is parallel to the first structure ST1. The first dummy structure STD1 includes a plurality of insulating interlayers 111 alternately stacked with a plurality of sacrificial layers 112. The sacrificial layers 112 include a material having an etching selectivity related to the etching selectivity of the insulating interlayers 111, for example, silicon nitride. The insulating interlayers 111 and the sacrificial layers 112 of the first dummy structure STD1 may be arranged corresponding to the insulating interlayers 111 and the conductive patterns 113 of the first structure ST1.

The alignment area AA including the first dummy structure STD1 includes at least one alignment key AK and a plurality of first dummy pillars DCP1.

The alignment key AK is formed in a recess R and includes an alignment layer Ma. The recess R is formed through the first dummy structure STD1. The recess R extends into the substrate 101. A depth d11 of the recess R extending into the substrate 101 is advantageously deeper than a depth of the device isolation trench. A diameter of the recess R is larger than a diameter of the first dummy pillar DCP1 at the uppermost surface of the dummy structure STD1. Because the recess R extends into the substrate 101, a defect such as a crack may form in the substrate 101 with respect to the recess R.

The alignment key AK includes the alignment layer Ma formed on surfaces of the dummy structure STD1 and surfaces of the substrate, which surfaces are adjacent to the recess R.

The first dummy pillars DCP1 in the alignment area AA are arranged around or to the side of the alignment key AK. The first dummy pillars DCP1 are formed through the first dummy structure STD1. The first dummy pillars DCP1 have a structure and a shape substantially the same as or similar to the structure and shape of the first channel pillar CP1. The first dummy pillar DCP1 is formed in a first key hole KH1 and includes a first memory layer ML1, a first channel layer CH1, and a first core layer CO1. The first dummy pillars DCP1 in the alignment area AA are spaced apart from each other by a gap substantially the same as a gap between the first channel pillars CP1. Alternatively, the gap between the first dummy pillars DCP1 may be wider than the gap between the first channel pillars CP1.

The first dummy structure STD1 includes a plurality of first dummy pillars DCP1 disposed in the overlay area OA. The first dummy pillars DCP1 disposed in the overlay area OA have a shape substantially the same as or similar to the shape of the first dummy pillars DCP1 in the alignment area AA.

At least one of the first dummy structures STD1 in the alignment area AA and the overlay area OA includes a plurality of first sacrificial pillars SP. The first sacrificial pillars SP may be spaced apart from the first dummy pillars DCP1 by a uniform gap. The sacrificial pillars SP have a height lower than a height of the dummy pillars DCP. The sacrificial pillars SP may have a height similar to the height of the first dummy structure STD1.

The second dummy structure STD2 is arranged on the first dummy structure STD1. The second dummy structure STD2 is positioned on a level substantially the same as the level of the second structure ST2. The second dummy structure STD2 includes a plurality of insulating interlayers 111 alternately stacked with a plurality of sacrificial layers 112. The second dummy structure STD2 has a height substantially the same as the height of the second structure ST2 in the third direction. The sacrificial layers 112 of the second dummy structure STD2 may be arranged corresponding to the conductive patterns 113 of the second structure ST2.

The second dummy structure STD2 includes a plurality of second dummy pillars DCP2. The second dummy pillars DCP2 have a configuration substantially the same as the configuration of the second channel pillars CP2. Each of the second dummy pillars DCP2 is formed in a second key hole KH2 and includes a second memory layer ML2, a second channel layer CH2, and a second core layer CO2. The second dummy pillars DCP2 are connected to at least one of the first dummy pillars DCP1.

The third dummy structure STD3 is arranged on the second dummy structure STD2. The third dummy structure STD3 is parallel to the second structure ST3. The third dummy structure STD3 includes a plurality of insulating interlayers 111 alternately stacked with a plurality of sacrificial layers 112. The third dummy structure STD3 has a height substantially the same as the height of the third structure ST3 in the third direction. The sacrificial layers 112 of the third dummy structure STD3 may be arranged corresponding to the conductive patterns 113 of the third structure ST3.

The third dummy structure STD3 includes a plurality of third dummy pillars DCP3. The third dummy pillars DCP3 have a configuration substantially the same as the configuration of the third channel pillars CP3. Each of the third dummy pillars DCP3 is formed incl a third key hole KH3 and includes a third memory layer ML3, a third channel layer CH3, and a third core layer CO3. The third dummy pillars DCP3 correspond and connect to the second dummy pillars DCP2. In an embodiment, an arrangement or layout of the third dummy pillars DCP3 in the third dummy structure STD3 is substantially the same as the arrangement or layout of the second dummy pillars DCP2 in the second dummy structure STD2.

According to an embodiment, the alignment area AA and the overlay area OA include the first dummy pillars DCP1, the second dummy pillars DCP2, and the third dummy pillars DCP3 formed through the dummy structures STD1, STD2, and STD3, respectively, around the alignment key AK, similar to the channel pillars CP1, CP2, and CP3 of the cell array region CA. The dummy pillars DCP1, DCP2, and DCP3 are formed around the alignment key AK in the first direction D1 and the second direction D2 in that the dummy pillars DCP1, DCP2, and DCP3 are not formed in the dummy structures in the third direction D3 above the dummy structure STD1 and/or STD2 in which the alignment key AK is formed. The dummy pillars DCP1, DCP2, and DCP3 surround the alignment key AK in the first direction D1 and the second direction D2, and do not coincide or overlap with the alignment key AK in the third direction D3 The alignment keys AK are formed between the dummy pillars DCP1, DCP2, and DCP3. The alignment keys AK may be formed only in the first dummy structure STD1 or may be formed in the first dummy structure STD1 and at least part of the second dummy structure STD2, but not the alignment keys AK are not formed in the third dummy structure STD3. The cracks that occur due to formation of the alignment key AK are blocked by the dummy pillars DCP1, DCP2, and DCP3 to prevent the crack from diffusing or spreading into the cell array region CA or reduced diffusing or spreading into the substrate may result.

The dummy pillars DCP1, DCP2, and DCP3 may be arranged corresponding to each other for each of the dummy structures STD1, STD2, and STD3 such that a misalignment and an overlay between the structures ST1, ST2, and ST3 in the cell array region CA may be easily observed.

In an embodiment, the alignment key AK is formed in the first dummy structure STD1 and the substrate 101, but is not limited to this example. For example, the alignment key AK may be formed in the first dummy structure STD1 and the second dummy structure STD2 to form an angled or high step.

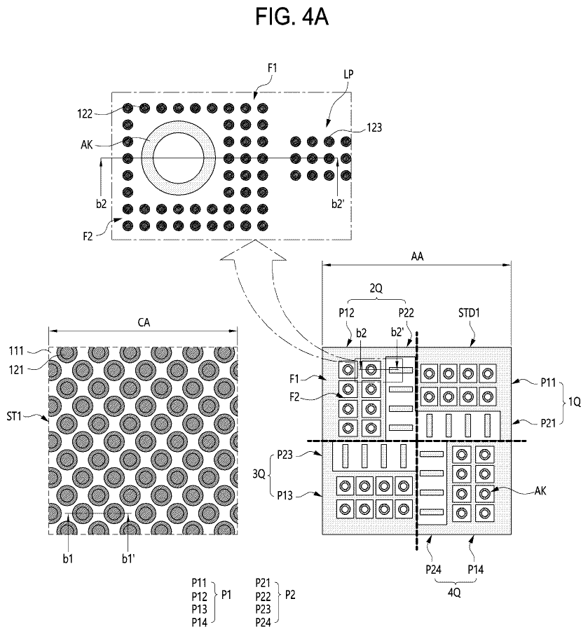

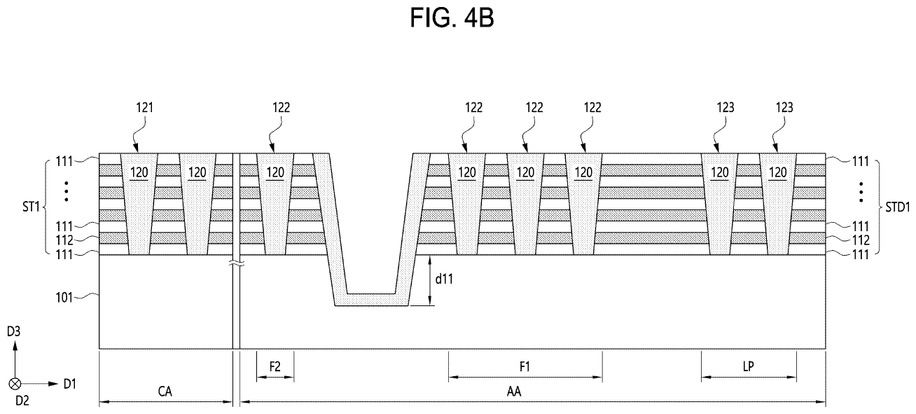

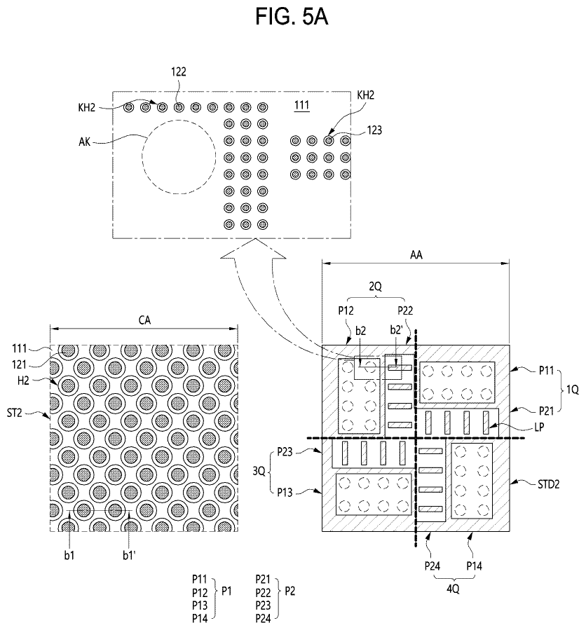

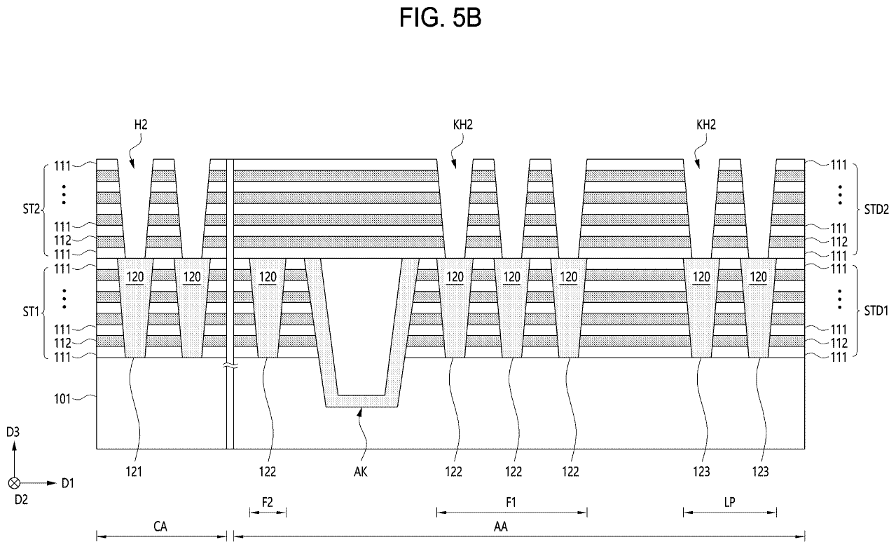

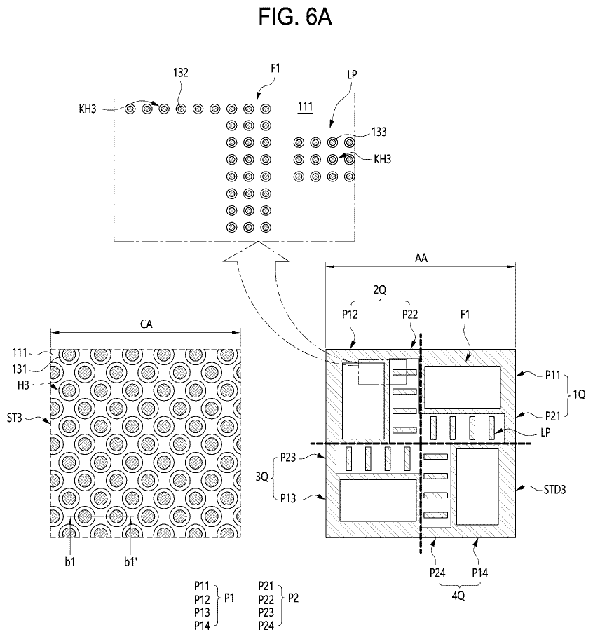

FIG. 4A, FIG. 5A, FIG. 6A, and FIG. 7A are plan views illustrating a semiconductor memory device formed utilizing a method of manufacturing a semiconductor memory device in accordance with an embodiment. FIG. 4B, FIG. 5B, FIG. 6B, and FIG. 7B are cross-sectional views illustrating a semiconductor memory device formed utilizing a method of manufacturing a semiconductor memory device in accordance with an embodiment. The cell array region CA in FIG. 4B, FIG. 5B, FIG. 6B, and 7B are cross-sectional views taken along a line b1-b1′ in FIG. 4A, FIG. 5A, FIG. 6A, and FIG. 7A, respectively. The alignment area AA in FIG. 4B, FIG. 5B, FIG. 6B, and 7B are cross-sectional views taken along a line b2-b2′ in FIG. 4A, FIG. 5A, FIG. 6A, and FIG. 7A, respectively.

Referring to FIG. 4A and FIG. 4B, a plurality of insulating interlayers 111 are alternately stacked with a plurality of sacrificial layers 112 on a substrate 101 including a cell array region CA and an alignment area AA to form a first preliminary structure ST1 in the cell array region CA and a first preliminary dummy structure STD1 in the alignment area AA.

The insulating interlayers 111, the sacrificial layers 112, and a portion of the substrate 101 having a thickness d11 in the first preliminary dummy structure STD1 are etched to form a plurality of recesses R in the first preliminary dummy structure STD1. The recesses R form an angled or high step in the alignment area AA. The insulating interlayers 111 and the sacrificial layers 112 in the first preliminary structure ST1 and the first preliminary dummy structure STD1 are etched to form a plurality of first channel holes H1 in the first preliminary structure ST1 and a plurality of first key holes KH1 in the first preliminary dummy structure STD1. For example, the first channel holes H1 and the first key holes KH1 have a same or similar size and a same or similar shape. The first channel holes H1 and the first key holes KH1 may be formed by a same or similar etching process. The first channel holes H1 and the first key holes KH1 may be formed before or after forming the recesses R. A width of the first channel holes H1 and a width of the first key holes KH1 may be significantly narrower than a width of the recess R. The first channel holes H1 and the first key holes KH1 may have gradually decreased diameters from top to bottom within the first preliminary structure ST1 and the first preliminary dummy structure STD1, for example, toward the substrate 101. The first channel holes H1 and the first key holes KH1 may have a high aspect ratio.

A first burying layer 120 may be formed in the first preliminary structure ST1 and the first preliminary dummy structure STD1 to fill the first channel holes H1 and the first key holes KH1. The first burying layer 120 may include materials corresponding to materials in the alignment layer Ma. Because the width of the recess R is greatly wider than the widths of the first channel holes H1 and the first key holes KH1, the first channel holes H1 and the first key holes KH1 may be fully filled with the first burying layer 120. The recess R may not be fully filled with the first burying layer 120. The first burying layer 120 may be formed on surfaces of the dummy structure STD1 and surfaces of the substrate 101, which surfaces are adjacent to the recess R. The first burying layer 120 may be planarized by a chemical mechanical polishing (CMP) process to expose upper surfaces of the first preliminary structure ST1 and the first preliminary dummy structure STD1. Thus, first sacrificial pillars 121, 122, and 123 are formed in the first channel holes H1 and the first key holes KH1. An alignment key AK is formed in the recess R.

In an embodiment, the sacrificial pillars 121, 122, and 123 and the alignment key AK provided functions including burying or embedding, an alignment key, and an etch stop layer. The first burying layer 120 in the sacrificial layer 120 and the alignment key AK have an etching selectivity relative to the insulating interlayers 111 and the sacrificial layers 112. The first burying layer 120 may also have gap-filling characteristic and an anti-scattered reflection characteristic. For example, the first burying layer 120 may include a stack structure including a gap-filling material, a metal, and an etch stop material. The gap-filling material may include an amorphous carbon layer. The metal may include tungsten, tantalum, and so forth. The etch stop material may include titanium nitride.

Viewed from a top or plan view such as shown in FIG. 4A, the first preliminary dummy structure STD1 in the alignment area AA is divided into a first quadrant 1Q, a second quadrant 2Q, a third quadrant 3Q, and a fourth quadrant 4Q. Each of the quadrants 1Q, 2Q, 3Q, and 4Q includes a dense pattern region P1 and a sparse pattern region P2.

The dense pattern region P1 includes the alignment keys AK and the first sacrificial pillars 122. The sparse pattern region P2 includes the first sacrificial pillars 123. A gap between the first sacrificial pillars 122 in the dense pattern region P1 may be substantially the same as a gap between the first sacrificial pillars 121 in the cell array region CA. A gap between the first sacrificial pillars 123 in the sparse pattern region P2 may be wider than the gap between the first sacrificial pillars 122.

For example, the first quadrant Q1 includes a first dense pattern region P11 and a first sparse pattern region P21. The alignment keys AK are arranged in the first dense pattern region P11 in a first arrangement. The first arrangement may be a 4×2 matrix, but is not limited to this example. The first sacrificial pillars 122 are positioned around the alignment keys AK. The first sacrificial pillars 122 are arranged in the first dense pattern region P11 to form a frame F1 and a grid F2. The first sacrificial layers 122 forming the frame F1 and the grid F2 are spaced apart from the alignment key AK.

The frame F1 is arranged around the alignment keys AK in the first arrangement. The grid F2 is positioned in the frame F1 to separate or isolate the alignment keys AK from each other. For example, a shortest distance between the first sacrificial pillar 122 and the alignment key AK may be about 0.4 μm to about 1 μm.

The first sacrificial pillars 123 are arranged in the first sparse pattern region P21 to form a plurality of line patterns LP. The gap between the first sacrificial pillars 123 may be wider than the gap between the first sacrificial pillars 122 in the first dense pattern region P11. The first dense pattern region P11 may be positioned near an edge of the first dummy structure STD1. The first sparse pattern region P21 may be positioned adjacent to or near the second quadrant 2Q.

The second quadrant Q2 includes a second dense pattern region P12 and a second sparse pattern region P22. The second dense pattern region P12 includes a plurality of the alignment keys AK and the first sacrificial pillars 122. The alignment keys AK are arranged in a second arrangement. The second arrangement may be a 2×4 matrix, but is not limited to this example. The second sparse pattern region P22 includes the first sacrificial pillars 123 arranged to form the line pattern LP. For example, a layout of the second dense pattern region P12 and the second sparse pattern region P22 may be similar to the layout of the first dense pattern region P12 and the first sparse pattern region P22 but rotated by about 270° or −90°.

The third quadrant 3Q includes a third dense pattern region P13 and a third sparse pattern region P23. A layout of the third dense pattern region P13 and the third sparse pattern region P23 may be similar to the layout of the first dense pattern region P12 and the first sparse pattern region P22 but rotated by about 180° or −180°.

The fourth quadrant 4Q includes a fourth dense pattern region P14 and a fourth sparse pattern region P24. A layout of the fourth dense pattern region P14 and the fourth sparse pattern region P24 may be substantially similar to the layout of the first dense pattern region P12 and the first sparse pattern region P22 but rotated by about 90° or −270°.

Referring to FIG. 5A and FIG. 5B, insulating interlayers 111 are alternately stacked with sacrificial layers 112 on the first preliminary structure ST1 and the first preliminary dummy structure STD1 to form a second preliminary structure ST2 on the first preliminary structure ST1 and a second preliminary dummy structure STD2 on the first preliminary dummy structure STD1. The insulating interlayers 111 and the sacrificial layers 112 of the second preliminary dummy structure STD2 have a stepped or angled shape where the alignment key AK is formed.

The insulating interlayers 111 and the sacrificial layers 112 of the second preliminary structure ST2 are etched until the first sacrificial pillars 121 are exposed to form a plurality of second channel holes H2. The insulating interlayers 111 and the sacrificial layers 112 of the second preliminary dummy structure STD2 are etched until the first sacrificial pillars 122 and 123 are wholly or partially exposed to form a plurality of second key holes KH2. When an overlay between the alignment key AK and a second sacrificial pillar may be formed later, the second key hole KH2 is configured to expose the first sacrificial pillars 122, which form the frame F1 of the dense pattern region P1, and the first sacrificial pillars 123, which form the line pattern LP of the sparse pattern region P2. An arrangement or layout of the second key holes KH2 in the alignment area AA may be similar to the structure shown in FIG. 4A. Alternatively, the second key holes KH2 may not be arranged in the grid F2.

The second channel holes H2 and the second key holes KH2 may have gradually decreased diameters from top to bottom of the second preliminary structure ST2 and the second preliminary dummy structure STD2.

In an embodiment, the recess for the alignment key AK is formed in the first preliminary dummy structure STD1 and the substrate 101. Alternatively, the recess may be formed in the second preliminary dummy structure STD2 and the first preliminary dummy structure STD1.

Referring to FIG. 6A and FIG. 6B, a second burying layer 130 is formed in the second preliminary structure ST2 and the second preliminary dummy structure STD2 to fill the second channel holes H2 and the second key holes KH2. The second burying layer 130 is planarized to form a plurality of second sacrificial pillars 131, 132, and 133 in the second channel holes H2 and the second key holes KH2. In an embodiment, the second burying layer 130 may include a material substantially the same as the material of the first burying layer 120. When the recess is formed in the second preliminary dummy structure STD2 and the first preliminary dummy structure STD1 (not shown), the alignment key AK is formed simultaneously with the second sacrificial pillars 131, 132, and 133.

The second sacrificial pillars 131 in the second preliminary structure ST2 are connected to the first sacrificial pillars 121 in the first preliminary structure ST1. The second sacrificial pillars 132 and 133 in the second preliminary dummy structure STD2 are connected to the first sacrificial pillars 122 and 123 in the first preliminary dummy structure STD1. For example, the second sacrificial pillars 132 are arranged in the dense pattern region P1 to form the frame F1. The second sacrificial pillars 133 are arranged in the sparse pattern region P2 to form the line patterns LP. The first sacrificial pillars 122 forming the grid F2 may be covered by the second preliminary dummy structure STD2, but may not be limited to this example. For example, the second sacrificial pillars 132 may be formed on the first sacrificial pillars 122.

Insulating interlayers 111 are alternately stacked with sacrificial layers 112 on the second preliminary structure ST2 and the second preliminary dummy structure STD2 including the second sacrificial pillars 131, 132, and 133 to form a third preliminary structure ST3 on the second preliminary structure ST2 and a third preliminary dummy structure STD3 on the second preliminary dummy structure STD2. The insulating interlayers 111 and the sacrificial layers 122 of the third preliminary dummy structure STD3 have an angled or stepped shape where the alignment key AK is formed.

The insulating interlayers 111 and the sacrificial layers 112 of the second preliminary structure ST2 are etched until the second sacrificial pillars 131 are exposed to form a plurality of third channel holes H3.

The insulating interlayers 111 and the sacrificial layers 112 of the third preliminary dummy structure STD3 are etched until the second sacrificial pillars 132 and 133 are exposed to form a plurality of third key holes KH3. An arrangement or layout of the third key holes KH3 may be substantially the same as the arrangement or layout of the second sacrificial pillars 132 and 133.

Referring to FIG. 7A and FIG. 7B, the second sacrificial pillars 131, 132, and 133, which are exposed through the third channel holes H3 and the third key holes KH3, and the first sacrificial pillars 121, 122, and 123 under and connected to the second sacrificial pillars 131, 132, and 133 are removed through the channel hole H and the key hole KH. The channel holes H are formed through the preliminary structures ST1, ST2, and ST3. The key holes KH are formed through the preliminary dummy structures STD1, STD2, and STD3.

A memory layer 140 having a conformal thickness is formed on surfaces of the dummy structure STD1 and surfaces of the substrate, which surfaces are adjacent to the channel hole H and the key hole KH. The memory layer 140 is formed by forming a blocking insulating layer, forming a data storage layer, and forming a tunnel insulating layer. The blocking layer, the data storage layer and the tunnel insulating layer may be formed by an atomic layer deposition (ALD) process. The memory layers 140 correspond to the memory layers ML1 to ML3 in FIG. 3.

A channel layer 145 having a conformal thickness is formed on the memory layer 140. The channel layer 145 corresponds to the channel layers CH1 to CH3 in FIG. 3.

A core layer 150 is formed in the third preliminary structure ST3 and the third preliminary dummy structure STD3 to fill the channel hole H and the key hole KH. The core layer 150 is planarized to be located within the channel hole H and the key hole KH. The core layer 150 may be additionally etched to reduce the height of the core layer 150 to a height lower than a height of the channel hole H and the key hole KH. The core layers 150 correspond to the core layer CO1 to CO3 in FIG. 3.

A semiconductor material is formed in the channel holes H and the key holes KH on the core layer 150 to form a capping layer 155. The capping layer 155 corresponds to the capping layer CAP in FIG. 3.

A plurality of channel pillars 161 are formed in the preliminary structures ST1 to ST3 in the cell array region CA. The dummy structures STD1 to STD3 are formed on the alignment area AA. The dummy structures STD1, STD2, and STD3 include a plurality of dummy pillars 162 and 163 that may have a shape substantially the same as or similar to a shape of the channel pillars 161.

The preliminary structures ST1 to ST3 are etched to form a slit S. The slit S is configured to separate the preliminary structures ST1 to ST3 into memory blocks. Sidewalls of the preliminary structures ST1 to ST3 are exposed through the slit S. The sacrificial layers 112 of the preliminary structures ST1 to ST3 may be selectively removed through the slit S and the sidewalls of the preliminary structures ST1 to ST3. A conductive material is formed in a space resulting from removing the sacrificial layers 112 to form conductive patterns 113 between the insulating interlayers 111. The conductive patterns 113 include at least one source selection line, a plurality of word lines, and at least one drain selection line in the memory block.

Because the slit S is not formed in the dummy structures STD1 to STD3, the sacrificial layers 112 in the dummy structures STD1 to STD3 are not replaced by the conductive pattern 113. Alternatively, the sacrificial layers 112 along an edge of the dummy structures STD1 to STD3 may be replaced by conductive patterns 113.

According to an embodiment, the alignment area includes the dummy structures and the dummy pillars formed through the dummy structures, similarly to the cell array region. The shape and the structure of the dummy pillars may be substantially the same as the shape and the structure of the channel pillars in the cell array region. The dummy pillars are arranged around the alignment key to prevent the cracks, which may be caused by forming the alignment key, from diffusing or spreading outward from the alignment key or to reduce diffusing or spreading in a direction toward the cell array region. For example, the height of the dummy pillars may be substantially the same as the height of the dummy structures to prevent or reduce the diffusion or spreading of the cracks.

The sacrificial pillars and/or the key holes may be formed in each of the dummy structures. An alignment between the channel pillars stacked on the cell region may be accurately observed by aligning the first sacrificial pillars with the second key holes and second sacrificial pillars with the third key holes.

The overlay may be measured by the gap between the alignment key and the dummy pillars.

In an embodiment, the dummy structures and the dummy pillars may be formed in the alignment area, but are not limited to this example. Alternatively, the dummy structures and the dummy pillars may be formed in the overlay area.

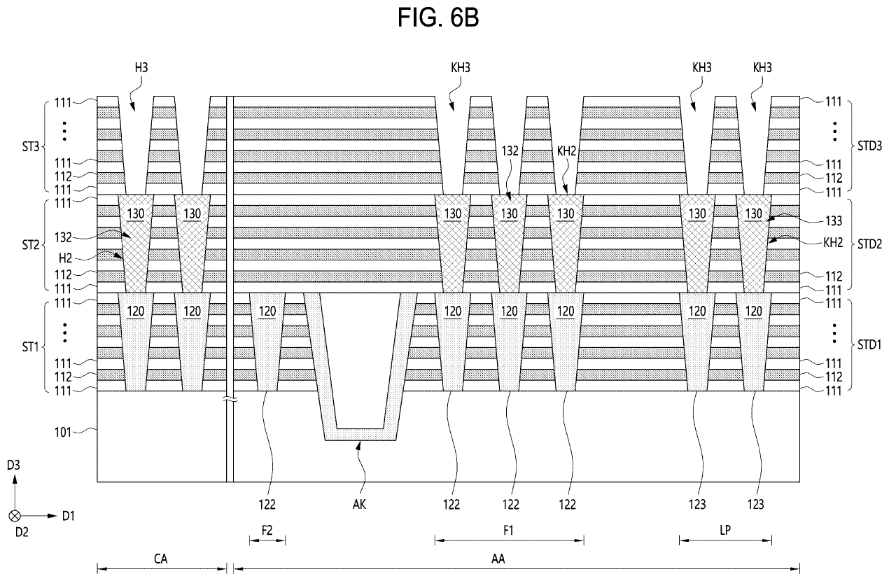

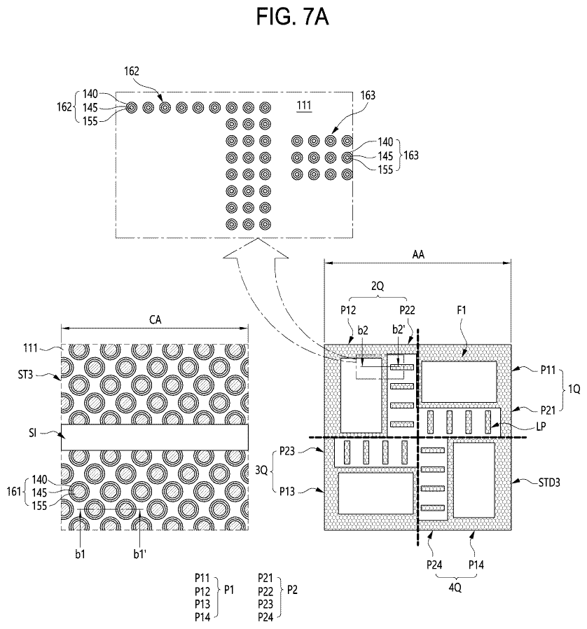

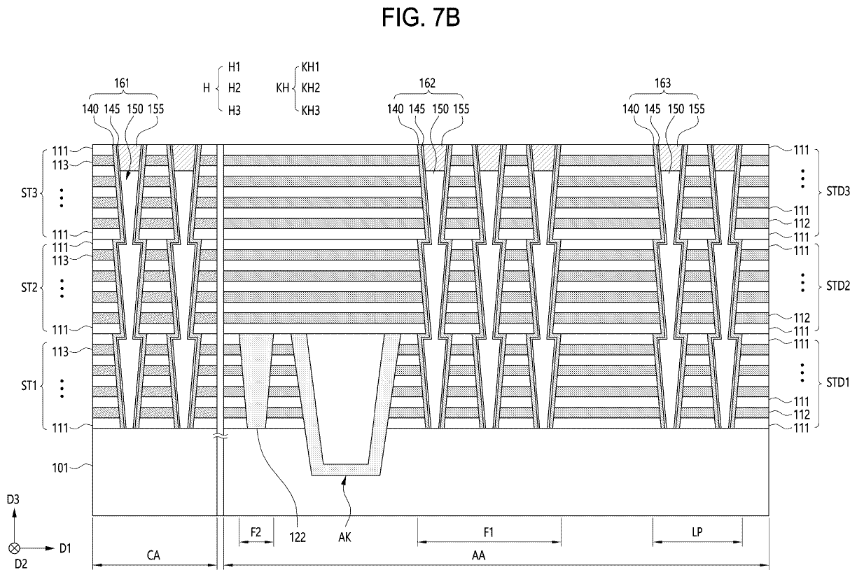

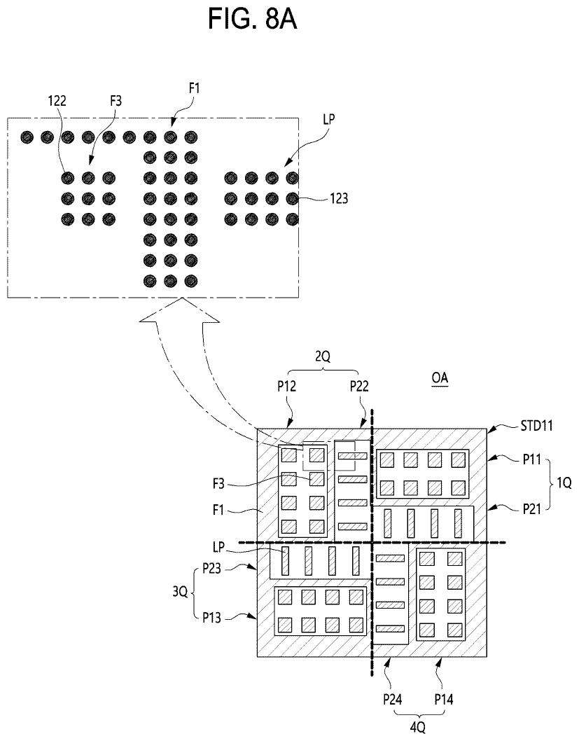

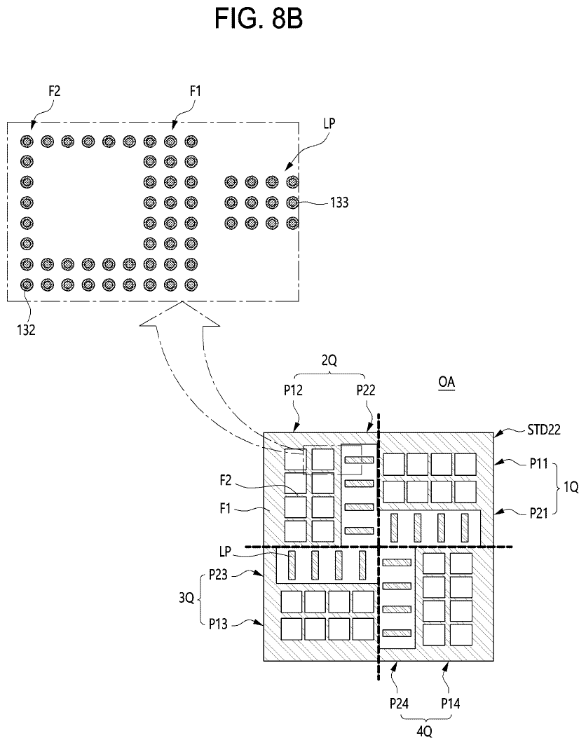

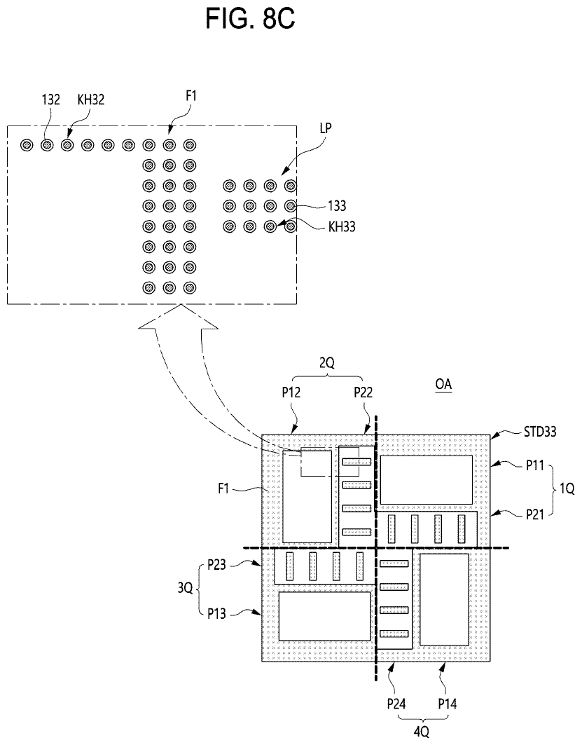

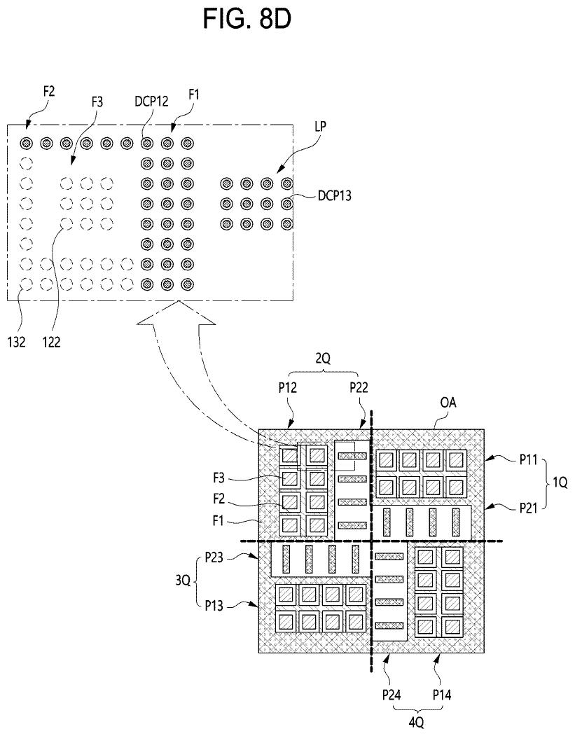

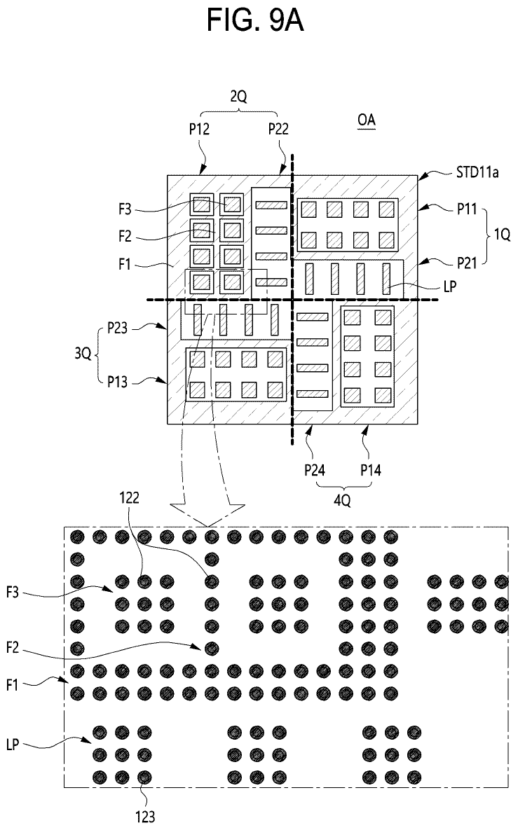

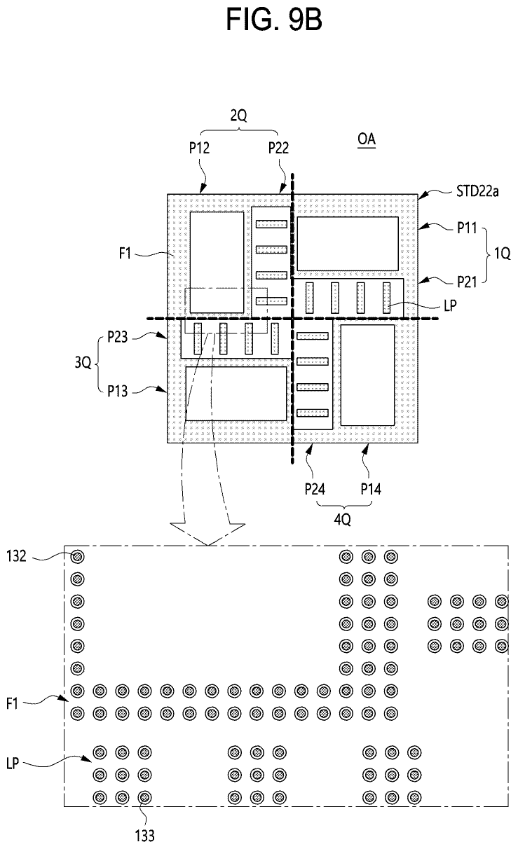

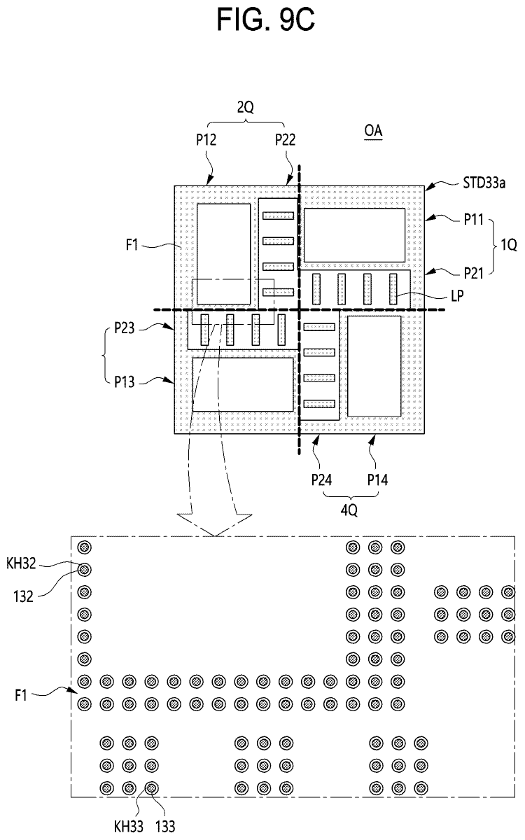

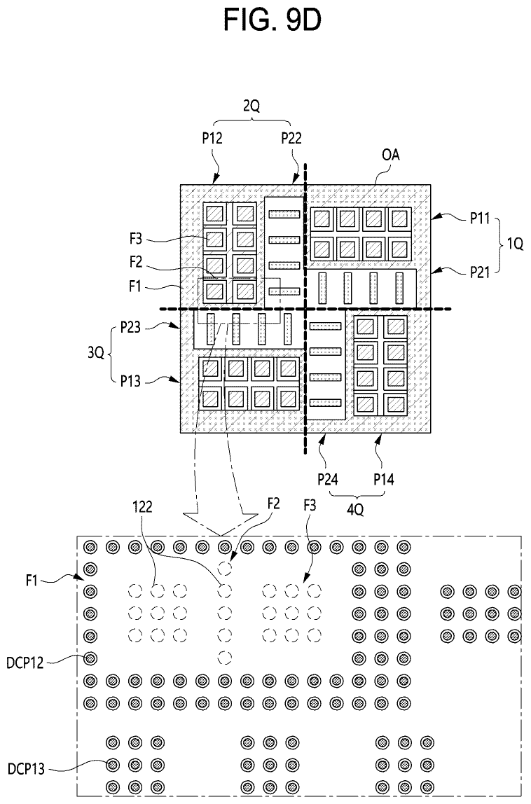

FIG. 8A to FIG. 8C are plan views illustrating a dummy structure for an overlay area in accordance with an embodiment. FIG. 8D is a plan view illustrating an overlay area in accordance with an embodiment. FIG. 9A to FIG. 9C are plan views illustrating a dummy structure of an overlay area in accordance with an embodiment. FIG. 9D is a plan view illustrating an overlay area in accordance with an embodiment.

As shown in FIG. 1 through FIG. 7D, the overlay area OA is positioned at one side of the alignment area AA of the scribe lane SL. The overlay area OA includes a first dummy structure STD11, a second dummy structure STD22, and a third dummy structure STD33 similar to the dummy structures STD1, STD2, and STD3 of the alignment area AA.

Referring to FIG. 8A, the first dummy structure STD11 of the overlay area OA is divided into quadrants 1Q to 4Q including dense pattern regions P11 to P14 and sparse pattern regions P21 to P21 similar to the alignment area AA.

Each of the dense pattern regions P11 to P14 includes a plurality of first sacrificial pillars 122 arranged in a frame F1 and a large pattern F3. For example, the large pattern F3 may be arranged in the frame F1 in the first arrangement or the second arrangement. The large pattern F3 may have a size corresponding to the size of the alignment key AK in the alignment area AA, but may have a different size. Each of the sparse pattern regions P21 to P24 includes a plurality of first sacrificial pillars 123 arranged in the line pattern LP. For example, a gap between the first sacrificial pillars 122 in the dense pattern region P11 to P14 may be substantially the same as or similar to the first gap between the channel pillars CP1 in the cell array region CA in FIG. 3. A gap between the first sacrificial pillars 123 in the sparse pattern region P21 to P24 may be wider than the first gap.

For example, the overlay may be measured according to the large pattern F3 including the first sacrificial pillars 122 and the frame F1 including the first sacrificial pillars 122.

The first sacrificial pillars 122 in the dense pattern regions P11 to P14 may be variously arranged. For example, as shown in FIG. 9A, the first sacrificial pillars 122 are arranged in the frame F1 and the grid F2 without the large pattern F3.

Referring to FIG. 8B, the overlay area OA, including the second dummy structure STD22 disposed on the first dummy structure STD11, is divided into a first quadrant 1Q, a second quadrant 2Q, a third quadrant 3Q, and a fourth quadrant 4Q. The quadrants 1Q to 4Q include dense pattern regions P11 to P14 and sparse pattern region P21 to P24. The dense pattern region P11 to P14 of the second dummy structure STD22 include a plurality of second sacrificial pillars 132 arranged in the frame F1 and the grid F2. The grid F2 may be positioned in the frame F1. The grid F2 may be configured to divide the large pattern F3. For example, an overlay may be measured by a distance between the second sacrificial pillars 132 arranged in the frame F1 and the grid F2 and the first sacrificial pillars 122 in the large patterns F2 of the first dummy structure STD11. The second sacrificial pillars 132 arranged in the frame F1 are arranged corresponding to the first sacrificial pillars 122 arranged in the frame F1. The sparse pattern region P21 to P24 of the second dummy structure STD22 further include a plurality of second sacrificial pillars 133 arranged in the line pattern LP. The second sacrificial pillars 133 arranged in the line pattern LP correspond to the first sacrificial pillars 123 arranged in the line pattern LP.

When the first dummy structure STD11a has a configuration such as shown in FIG. 9A, in order to measure an overlay between the second sacrificial pillars 132 of the second dummy structure STD22a and the first sacrificial pillars 122 under the second sacrificial pillars 132, the second sacrificial pillars 132 are arranged in the frame F1 and the line pattern LP, but are not limited to this example.

Referring to FIG. 8C, the third dummy structure STD33 disposed on the second dummy structure STD22 is divided into quadrants 1Q to 4Q. Each of the quadrants 1Q to 4Q includes dense pattern regions P11 to P14 and sparse pattern regions P21 to P24. The dense pattern regions P11 to P14 of the third dummy structure STD33 include key holes KH32 configured to expose the second sacrificial pillars 132 arranged in the frame F1. The sparse pattern regions P21 to P24 of the third dummy structure STD33 include key holes KH33 configured to expose the second sacrificial pillars 133 arranged in the line pattern LP.

When the second dummy structure STD22a has a configuration such as shown in FIG. 9B, the third dummy structure STD33a in FIG. 9C includes key holes KH32 and KH33 configured to expose the second sacrificial pillars 132 in the frame F1 and the line pattern LP similar to the second dummy structure STD22a.

Referring to FIG. 8D, the overlay area OA includes the first dummy structure STD11, the second dummy structure STD22, and the third dummy structure STD33 sequentially stacked.

The first sacrificial pillars 122 and 132 in the frame F1 and the line pattern LP of the dummy structures STD11 and STD22 are removed through the key holes KH2 and KH3 resulting in dummy key holes. Pillar material such as a memory layer, a channel layer, a core layer, and a capping layer is formed in the dummy key holes resulting in dummy pillars DCP12 and DCP13. The first sacrificial pillars 122 in the large pattern F3 and the second sacrificial pillars 132 in the grid F2 are covered by the dummy structures STD22 and STD33. Thus, the overlay area OA may be measured by a distance between the first sacrificial pillars 122 and the second sacrificial pillars 132, between a distance between first sacrificial pillars 122 and the dummy pillars DCP12 and DCP13, and a distance between the second sacrificial pillars 132 and the dummy pillars DCP12 and DCP13.

In FIG. 9D, the first sacrificial pillars 122, the second sacrificial pillars 132, and the key hole KH2 in the frame F1 of the overlay area OA are replaced by the dummy pillars DPC12. The first sacrificial pillars 123, the second sacrificial pillars 133, and the key hole KH3 in the line pattern LP are replaced by the dummy pillars DCP13.

The first sacrificial pillars 122 in the grid F2 of the first dummy structure STD11a are covered by the structures STD22a and STD33a disposed on the first dummy structure STD11a. Thus, the overlay area OA may be measured by a distance between the first sacrificial pillars 122 and the dummy pillars DCP12 and DCP13.

In an embodiment, the alignment area AA and the overlay area OA may have various configurations, layouts, and/or shapes as well as the configurations, layouts, and/or shapes depicted in drawings.

According to an embodiment, at least one of the alignment area and the overlay area includes the dummy structures and the dummy pillars formed through the dummy structures. Because the dummy pillars have substantially the same shape as the shape of the channel pillar in the cell array region, any crack caused by the stepped or angled sections within the alignment area, such as the alignment key, and the overlay area may be prevented from diffusing or spreading into the substrate toward the cell array region or reduced diffusing or spreading into the substrate may result.

Further, the dummy pillars or the sacrificial pillars are provided within each of the dummy structures to readily measure the alignment and the overlay between the stacked dummy structures.

The described embodiments illustrate and are not limited the examples provided. Various alternatives and equivalents are possible. The present disclosure is not limited by the embodiments described and is not limited to any specific type of semiconductor device. All changes within the meaning and range of equivalency of the claims are included within their scope.

What is claimed is:

1. A semiconductor memory device comprising:
a chip formed in a cell array region of a substrate and including a plurality of structures and a plurality of channel pillars formed through the plurality of structures; and
a plurality of dummy structures, at least one alignment key, and a first plurality of dummy pillars formed in an alignment area of a scribe lane of the substrate, the scribe lane configured to facilitate separation of a plurality of chips;
wherein the at least one alignment key extends through at least one of the plurality of dummy structures and extends into the substrate; and
wherein the first plurality of dummy pillars is formed through the plurality of dummy structures and is formed around the alignment key.

2. The semiconductor memory device of claim 1, wherein the plurality of channel pillars and the first plurality of dummy pillars have a similar shape and a similar structure.

3. The semiconductor memory device of claim 1, wherein the plurality of structures and the first plurality of dummy structures have a similar height.

4. The semiconductor memory device of claim 1, wherein each of the plurality of structures comprises a plurality of insulating interlayers and a plurality of conductive patterns.

5. The semiconductor memory device of claim 1, wherein each of the plurality of dummy structures comprises a plurality of insulating interlayers and a plurality of sacrificial layers.

6. The semiconductor memory device of claim 1, wherein the plurality of channel pillars are spaced apart from each other by a first gap, and at least two of the first plurality of dummy pillars are spaced apart from each other by the first gap.

7. The semiconductor memory device of claim 6, wherein the alignment area comprises:
at least one dense pattern region in which the alignment key and a first group of the first plurality of dummy pillars spaced apart from each other by the first gap are disposed; and
at least one sparse pattern region positioned adjacent to the dense pattern region, wherein a second group of the first plurality of dummy pillars is disposed in the at least one sparse pattern region and is spaced apart from each other by a second gap wider than the first gap.

8. The semiconductor memory device of claim 7, wherein the dense pattern region comprises a plurality of sacrificial pillars arranged between the first group of the first plurality of dummy pillars, and the plurality of sacrificial pillars have a height lower than a height of the first plurality of dummy pillars.

9. The semiconductor memory device of claim 1, wherein the scribe lane includes an overlay area near the alignment area,
wherein:
the plurality of dummy structures are formed in the overlay area of the scribe lane;
a second plurality of dummy pillars is formed through the plurality of dummy structures in the overlay area; and
a plurality of sacrificial pillars disposed in the overlay area and spaced apart from the second plurality of dummy pillars by a gap, the plurality of sacrificial pillars having a height lower than a height of the second plurality of dummy pillars.

10. The semiconductor memory device of claim 9, wherein the overlay area comprises:
at least one dense pattern region in which a first group of the second plurality of dummy pillars spaced apart from each other by a first gap is disposed; and
at least one sparse pattern region positioned adjacent to the dense pattern region, wherein a second group of the second plurality of dummy pillars is disposed in the at least one sparse pattern region and is spaced apart from each other by a second gap wider than the first gap;
wherein the plurality of sacrificial pillars are arranged in the dense pattern region.

11. A semiconductor memory device comprising:
a first structure formed in a cell array region of a substrate, a second structure arranged on the first structure, and a third structure arranged on the second structure, the first structure including a plurality of first channel pillars, the second structure including a plurality of second channel pillars corresponding to the plurality of first channel pillars, and the third structure including a plurality of third channel pillars corresponding to the plurality of second channel pillars; and
a first dummy structure formed in an alignment area of the substrate, a second dummy structure arranged on the first dummy structure, and a third dummy structure arranged on the second dummy structure, the first dummy structure including a plurality of alignment keys disposed between a plurality of first dummy pillars, the second dummy structure including a plurality of second dummy pillars corresponding to the plurality of first dummy pillars, the third dummy structure including a plurality of third dummy pillars corresponding to the second dummy pillars.

12. The semiconductor memory device of claim 11, wherein the first dummy structure, the second dummy structure arranged on the first dummy structure, and the third dummy structure arranged on the second dummy structure are formed in an overlay area of a scribe lane of the substrate,
wherein at least the first dummy structure comprises a plurality of sacrificial pillars spaced apart from a second plurality of first dummy pillars by gap in the overlay area.

13. The semiconductor memory device of claim 11,
wherein the plurality of first channel pillars and the plurality of first dummy pillars have a similar shape and a similar structure,
wherein the plurality of second channel pillars and the plurality of second dummy pillars have a similar shape and a similar structure, and
wherein the plurality of third channel pillars and the plurality of third dummy pillars have a similar shape and a similar structure.

14. The semiconductor memory device of claim 11, wherein at least one of the first structure, the second structure, and the third structure comprises a plurality of insulating interlayers alternately stacked with a plurality of conductive patterns.

15. The semiconductor memory device of claim 11, wherein at least one of the first dummy structure, the second dummy structure, and the third dummy structure comprises a plurality of insulating interlayers alternately stacked with a plurality of sacrificial layers alternately stacked.

16. A method of manufacturing a semiconductor memory device, the method comprising:
alternately stacking a first plurality of insulating interlayers with a first plurality of sacrificial layers to form a first preliminary structure on a cell array region of a substrate and to form a first preliminary dummy structure on a scribe lane of the substrate;
forming a plurality of first sacrificial pillars in the first preliminary structure and the first preliminary dummy structure;
alternately stacking a second plurality of insulating interlayers with a second plurality of sacrificial layers on the first preliminary structure and the first preliminary dummy structure to form a second preliminary structure on the first preliminary structure and to form a second preliminary dummy structure on the first preliminary dummy structure;
forming a plurality of second sacrificial pillars in the second preliminary structure and the second preliminary dummy structure, wherein each of the plurality of second sacrificial pillars is connected to a different one of the plurality of first sacrificial pillars;
alternately stacking a third plurality of insulating interlayers with a third plurality of sacrificial layers on the second preliminary structure and the second preliminary dummy structure to form a third preliminary structure on the second preliminary structure and a third preliminary dummy structure on the second preliminary dummy structure;
forming a plurality of holes in the third preliminary structure and the third preliminary dummy structure to expose the plurality of second sacrificial pillars;
removing the plurality of second sacrificial pillars and the plurality of first sacrificial pillars exposed through the plurality of holes to form a plurality of channel holes through the first preliminary structure, the second preliminary structure, and the third preliminary structure and to form a plurality of key holes through the first preliminary dummy structure, the second preliminary dummy structure, and the third preliminary dummy structure;
filling the plurality of channel holes and the plurality of key holes; and
forming at least one alignment key between the plurality of first sacrificial pillars in the first preliminary dummy structure.

17. The method of claim 16, wherein filling the channel holes and the key holes comprises:
forming a memory layer on sidewalls of the first preliminary structure, the second preliminary structure, and the third preliminary structure, which sidewalls are adjacent to the plurality of channel holes and on sidewalls of the first preliminary dummy structure, the second preliminary dummy structure, and the third preliminary dummy structure, which sidewalls are adjacent to the plurality of key holes;
forming a channel layer on the memory layer;
forming a core layer the channel layer; and
forming a capping layer on the core layer.

18. The method of claim 16, further comprising:
etching the first preliminary structure, the second preliminary structure, and the third preliminary structure to form a slit; and
replacing the first plurality of sacrificial layers, the second plurality of sacrificial layers, and the third plurality of sacrificial layers exposed through the slit with a plurality of conductive layers.

19. A semiconductor memory device comprising:
a substrate including a cell array region and a scribe lane;
a first plurality of insulating interlayers alternately stacked with a first plurality of second layers and forming a first structure on the cell array region and a first dummy structure on the scribe lane;
a second plurality of insulating interlayers alternately stacked with a second plurality of second layers and forming a second structure on the first structure and a second dummy structure on the first dummy structure;
a third plurality of insulating interlayers alternately stacked with a third plurality of second layers and forming a third structure on the second structure and a third dummy structure on the second dummy structure;
a plurality of dummy channel pillars formed through the first dummy structure, the second dummy structure, and the third dummy structure; and
a plurality of alignment keys disposed in the first dummy structure between the plurality of dummy pillars, wherein the plurality of alignment keys do not extend into the third dummy structure.

20. The semiconductor memory device of claim 19, further comprising a plurality of channel pillars formed through the first structure, the second structure, and the third structure, wherein the first plurality of second layers, the second plurality of second layers, and the third plurality of second layers comprise conductive patterns in the first structure, the second structure, and the third structure and comprise sacrificial layers in the first dummy structure, the second dummy structure, and the third dummy structure.
